(19) United States
(12) Patent Application Publication
(10) Pub. No.: US 2009/0231042 A1
(43) Pub. Date: Sep. 17, 2009

(54) Broadband Power Amplifier with A High Power Feedback Structure

(76) Inventors: Pengcheng Jia, Thousand Oaks, CA (US); Patrick Gordon Courtney, Camarillo, CA (US)

Correspondence Address: Pengcheng Jia, Apt 205, 442 Wilbur Road, Thousand Oaks, CA, 91360, US

(21) Appl. No.: 12/126,753

(22) Filed: May 23, 2008

Related U.S. Application Data
(60) Provisional application No. 60/969,953, filed on Sep. 5, 2007.

(51) Int. Cl. H03F 1/00

(52) U.S. Cl. 330/291

(57) ABSTRACT

A broadband power amplifier using a novel high power feedback structure is disclosed in this patent. Feedback is widely used in amplifier design to broaden the bandwidth of the amplifier. Traditionally, the feedback resistor is either an axial resistor placed over the top of the transistor or a surface mount resistor with a long PCB trace making up the rest of the feedback path. However, each of these methods has it's limitations. The axial resistor doesn't have good heat sinking capability and therefore cannot handle high power. The feedback on PCB makes the feedback path long and becomes positive feedback at high frequency, thus limiting the high end frequency of operation of the amplifier in a stable region. The feedback structure disclosed in this patent has a good heat sinking path, has very short feedback path; allowing for higher frequency operation. We successfully applied the feedback structures to a Gallium Nitride (GaN) transistor, which is a new type of power transistor that has low parasitic capacitance and high optimum load impedance, and demonstrated an amplifier with very high output power over extraordinarily broad bandwidth. Matching networks have been optimized to improve performance and stability. We have demonstrated that unconditional stability is achievable while operating over a broad bandwidth using this feedback structure.

This application claim an invention disclosed in prior-filed provisional application (Application # 60/939,953)

### BACKGROUND OF THE INVENTION

1. Field of Invention

This invention relates to power amplifier designs using feedback structures.

2. Description of Prior Art

Feedback structures have been widely used with amplifiers to broaden the bandwidth, improve the linearity, etc. It also helps to improve the input and output impedance match. Feedback structure normally consists of a resistor and a blocking capacitor. It connects between the input and output of a transistor and is typically used as a negative feedback.

For low power applications, the feedback structures are typically laid on the PCB in discrete circuits or on the substrate in the integrated circuits. The power rating for the feedback resistor is normally low.

For power amplifiers, the transistor used typically has a flange type of package which provides good heat sinking for the transistor die and also is easily mounted into a metal chassis. However, the flange type of package is large comparing to the low power packages. If the feedback is laid on the PCB, it must go around the flange package. This long feedback path will increase the phase delay and at a high enough frequency the negative feedback will change to positive feedback and send the amplifier into an unstable region and possibly causing oscillation.

Due to slow electron mobility, a broadband power amplifier using a Silicon transistor can only work up to about 1 GHz typically. The emerging GaN transistor has very high output power capability and can also work up to much higher frequency comparing to the conventional Silicon transistors. The high gain of the GaN transistor at high frequency can easily cause oscillation if a long feedback path is applied to the transistor.

Axial resistors are used over the top of the flange package to reduce the length of the feedback path. A capacitor is mounted on one side of the transistor; one lead of the axial resistor connects to the capacitor and the other lead connects to the other side of the transistor. However, the axial resistors have to dissipate the heat into the air, thus limiting the power handling capability. In order to overcome this the resistors must be made larger, but the increase in the length of the resistor will add more phase delay and therefore limit the high end frequency of operation where the feedback will remain negative and the amplifier will remain stable.

Here an innovative feedback structure is disclosed. It has a good heat sinking structure in a very compact form. The feedback length is minimized and the broadband amplifier can output high power up to a very high frequency and remain unconditionally stable.

### BRIEF SUMMARY OF THE INVENTION

A broadband power amplifier with high power feedback structure is disclosed. In one embodiment, the amplifier has demonstrated to be able to output more than 20 Watts of power over an extraordinary broad 20 MHz to 2500 MHz bandwidth. The amplifier combines the advantage of a new type of power transistor, GaN transistor, and a unique high power feedback structure. GaN transistors have high breakdown voltage and much larger optimum load impedance comparing to other types of conventional transistors making them ideal for broadband amplifier design. With a GaN transistor, more output power can be achieved over a broader frequency band. The disclosed feedback structure is able to dissipate a large amount of heat and has a minimized phase delay. It will fully realize the capability of the new GaN transistors. The feedback structure includes a metal bridge and a power resistor which is mounted on the bridge. The metal bridge goes across the flange package of the transistor. The 2 posts of the bridge have through mounting holes respectively. The screws go through the bridge and tighten the bridge over the top of the transistor to the metal chassis. A power resistor can be mounted on different sides of the bridge. Leads are attached to the resistor and connect the resistor to the PCB trace on one side and a capacitor on the other side.

In one embodiment, the bridge is tightened to the flange package of a transistor, then to the metal chassis. The heat generated from the resistor will dissipate through the bridge and flange, then into the chassis. The thermal resistance has been reduced greatly comparing to resistors radiating heat into the air or into a PCB. The feedback structure can handle high power and be used in very high power amplifier systems.

Because the feedback path phase delay is minimized, matching networks can be optimized to enable the amplifier to operate stably. This amplifier is the very first ultra-broadband stable high power feedback GaN amplifier.

With the special structure and choices of those materials, the thermal resistance from the resistor to the chassis is minimized. In one embodiment, the resistor will be able to handle greater than 10 Watts of heat. Higher power handling can also be achieved with bigger bridge or other bridge material that has higher thermal conductivity. For ultra broadband amplifier, a lot of power will be dropped on to the feedback resistor. Improving the thermal resistance of the feedback resistor can greatly increase the output power capability of the amplifier system. In the meanwhile, because of the resistor is mounted right on top of the transistor, the length of the feedback path is minimized. It can be used as feedback resistor for amplifiers up to several GHz.

The feedback amplifier design is not limited to GaN transistors. The high power feedback structure can also be used with high performance Silicon, Silicon Carbide or GaAs transistors (such as LDMOS or GaAs MESFET, pHEMT) or their integrated circuits to achieve high output power over extraordinary bandwidth.

Multiple stages of the feedback amplifier have been connected to increase the gain of the amplifier. By further optimizing the inter-stage matching, the multi-stage amplifier can operate with high output high power and gain across the extra broad bandwidth, while remaining unconditionally stable.

The feedback structure can also help to improve the linearity of the amplifier. A linear high power feedback amplifier can also be achieved with the high power feedback structure.

### BRIEF DESCRIPTION OF THE SEVERAL VIEWS OF THE DRAWINGS

Many advantages of the present invention will be apparent to those skilled in the art with a reading of this specification in conjunction with the attached drawings, wherein like reference numerals are applied to like elements, and wherein:

FIG. 1 is a transistor in a flange package.

FIG. 2 is metal bridge for feedback resistor.

FIG. 3 is high power surface mount resistor.

FIG. 4 is a perspective view of the feedback structure mounted on transistor.

FIG. 5 is a perspective view of another embodiment of the feedback structure mounted on transistor.

FIG. 6 is a perspective view of a third embodiment of the feedback structure mounted on transistor.

### DETAILED DESCRIPTION OF THE INVENTION

The terminology used in the description presented herein is not intended to be interpreted in any limited or restrictive manner, simply because it is being utilized in conjunction with a detailed description of certain specific embodiment of the invention. Furthermore, embodiments of the invention can include several novel features, no single one of which is solely responsible for its desirable attributes or which is essential to practicing the invention herein described.

Embodiments of a broadband power amplifier with a high power feedback structure are described. A feedback resistor can flatten the gain of an active device over a broad frequency range, and also improve the input and output impedance matching. To increase the power handling of the feedback resistor, a metal bridge is used to mount a surface mount power resistor. The metal bridge is mounted right on top the active device to shorten the feedback path. High power broadband amplifier can be achieved for a high power active device using this high power feedback structure.

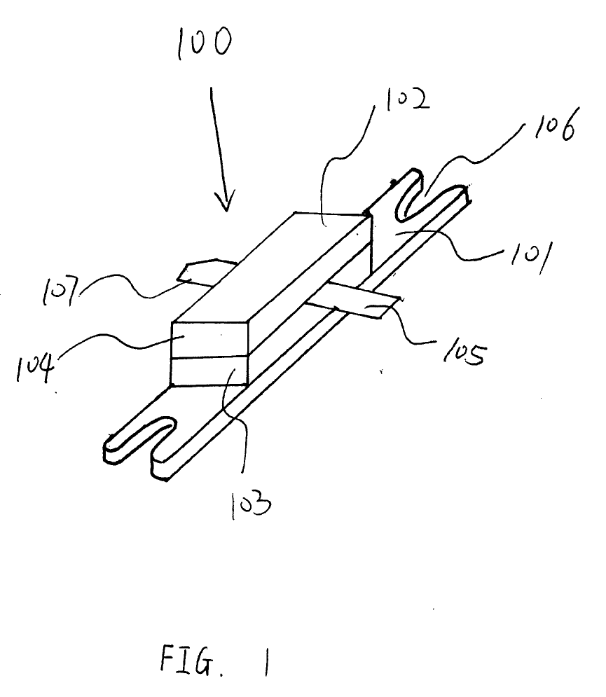

Active device in amplifiers magnifies a small signal at its input and output a much larger signal. An active device can either be a transistor or integrated circuit. In the preferred embodiment, a transistor is used as the active device. Most of the high power transistors use flange packages as shown in FIG. 1. The transistor 100 has a metal base 101 and a ceramic portion 102. The ceramic portion 102 includes a ceramic ring frame 103 and a ceramic lid 104. Metal leads 105 and 107 go through the ceramic portion 103 to bring RF and DC signal in and out of the ceramic portion. Lead 107 is on the input side and lead 105 is on the output side. One or a plurality of power transistor die or IC (integrated circuit) is mounted on the metal base 101 inside the ceramic portion 102. The metal base 101 has cutout regions 106 on each side. Some embodiments have holes instead of cutout regions 106. Screws will go though those cutout regions 106 and tighten the package to a metal chassis. Good heat dissipation is achieved by this type of package. In other embodiments, the transistor uses a flangeless package which has a metal base that is the same size as the ceramic portion.

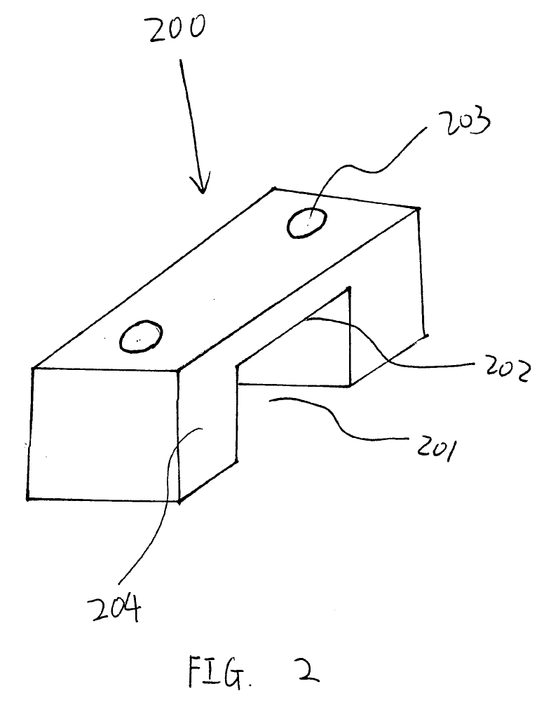

In the preferred embodiment, the metal bridge 200 is designed to match the dimensions of the transistor as shown in FIG. 2. The metal bridge has a recess region 201 in the middle to accommodate the ceramic portion 102 of the flange package. The recess region 201 in the bridge is higher than the ceramic portion of the flange package 102. When the bridge 200 is mounted on top of the flange package 100, there is clearance between the top of the recess region 202 and the top of the ceramic lid 104. Through holes 203 are drilled in the posts 204. The position of the holes matches with the cutout area 106 of the flange package.

The metal bridge is not limited to the reverse “U” shape. In other embodiments, it can has only one post region and only 1 screw hole, just as a metal block.

In other embodiments, the bridge can also be made of non-metal material that has high thermal conductivity.

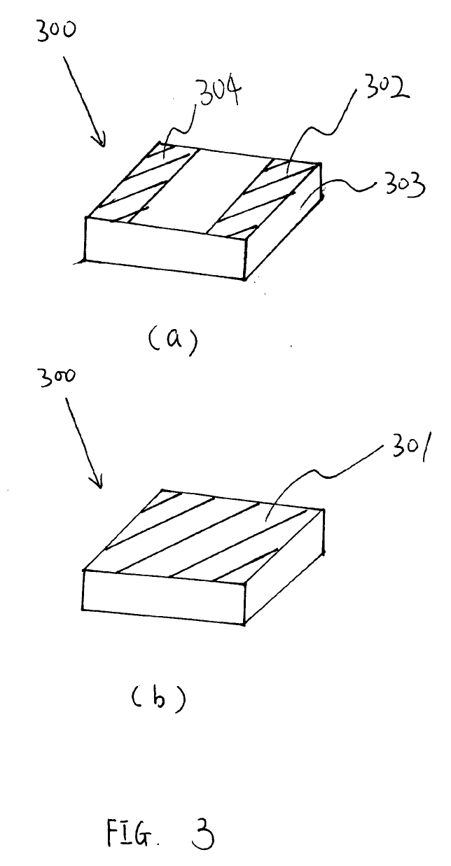

High power resistor 300 is used as the feedback resistor. In one embodiment, the high power resistor 300 has metal plated pads 302 and 304 on the top side as shown in FIG. 3(a). It can also have metal plating 301 on the back side as shown in FIG. 3(b). The resistors body 303 is typically made by AlN or BeO substrate. The resistor substrate 303 has very high thermal conductivity and hence can dissipate heat very well.

The resistor 300 can be soldered to the bridge 200 or epoxy attached to it. The bridge 200 can be made of aluminum, copper or other material. Copper is preferred since it has very high thermal conductivity with reasonable pricing. In one embodiment, the bridge is plated with Nickel. Other plating material can also be used for resistor attachment and for better protection from erosion and oxidation.

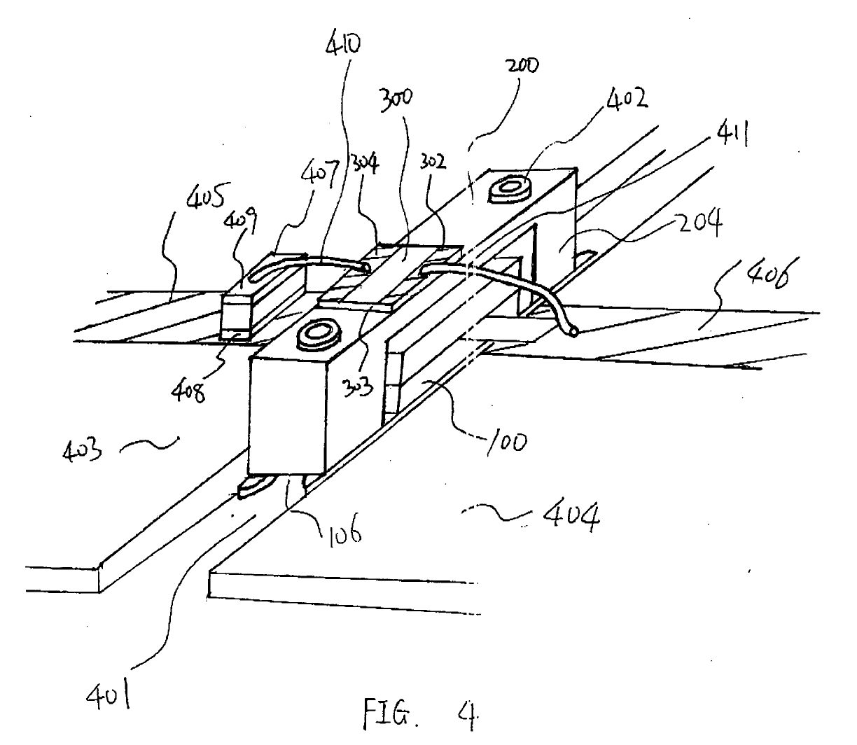

In one embodiment, the bridge 200 and resistor 300 is assembled with the transistor 100 to a chassis 401 as shown in FIG. 4. Screws 402 go through the post 204 of the bridge 200 and cut out regions 106 in the package base 101, and tighten both the bridge 200 and transistor 100 to the chassis 401. Resistor 300 is soldered to the top surface of bridge 200. Input trace 405 is printed on the input PCB 403. Output trace 406 is printed on output PCB 404. In one embodiment, a ceramic capacitor 407 is place on the input trace 405. One of the capacitor's terminals, 408, is soldered to the trace, 405. The other terminal, 409, connects to the pad 304 of the resistor 300 by a metal wire 410. The other pad 302 of the resistor 300 connects to the output trace 406 by metal wire 411. In other embodiments, the capacitor 407 can be another type of capacitor, such as tantalum or electrolytic. And the wires 410 and 411 can be metal ribbons or traces.

The posts 204 of the bridge contact with the flange base 101 of the package and the flange base 101 also contacts with the chassis. Thermal grease or gap filler materials can be used to remove air voids at the interfaces. A thermal path is provided from the resistor 200 though the resistor substrate 303 to the bridge 200, though the posts 204 and flange base 101, then into the chassis 401. The heat will be ultimately conducted to a heatsink that the chassis is mounted onto.

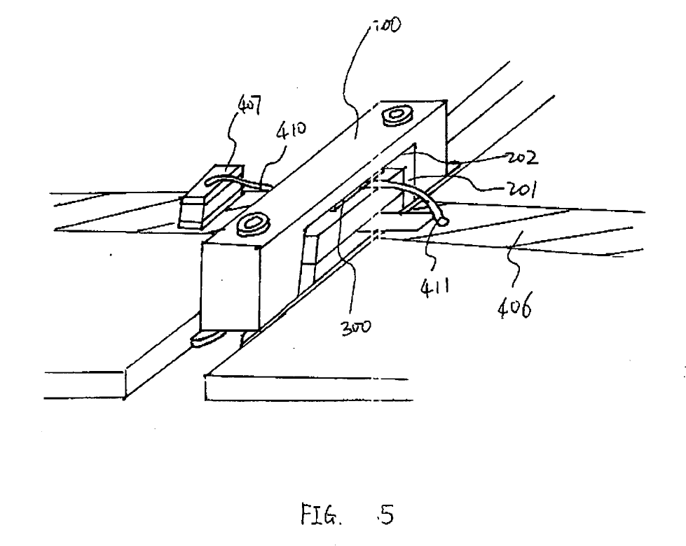

In one embodiment as shown in FIG. 5, the resistor 300 is mounted on the back side of the bridge 200. The resistor 300 is in the recess region 201 of the bridge 200 and soldered to the surface 202 of the bridge 200. Metal wire 410 connects one side of the resistor to capacitor 407 and metal wire 411 connects the other side of the resistor to output trace 406.

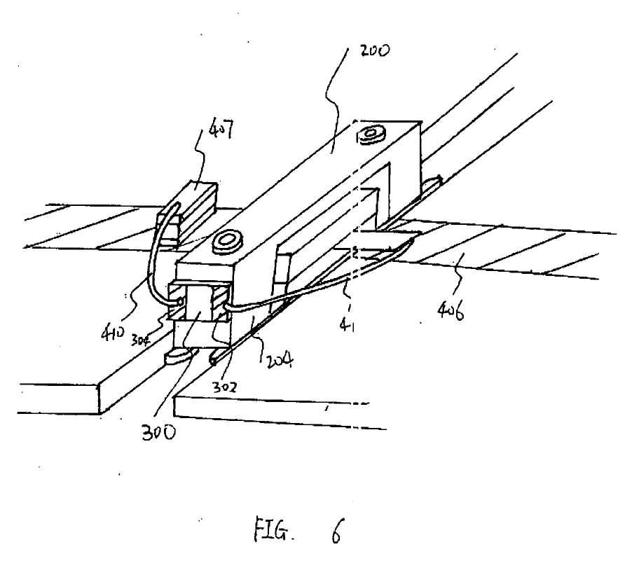

In one embodiment as shown in FIG. 6, the resistor 300 is mounted on side of the bridge 200. The resistor 300 is soldered to the side of the post 204 of the bridge 200. Metal wire 410 connects one side of the resistor to capacitor 407 and metal wire 411 connects the other side of the resistor to output trace 406.

The capacitor 407 is used to block DC voltage from the output of the transistor to the input of the transistor. In other embodiments, the capacitor 407 can be placed on top of output trace 406. Then the wire 410 will connect input trace 405 and pad 304 of the resistor 200 and wire 411 will connect pad 302 of the resistor 200 and top terminal, 409, of the capacitor. In another embodiment, no blocking capacitor is used when blocking capacitors are placed inside the package.

In other embodiments, the resistor can be an axial resistor. It can be epoxy attached to the metal bridge and conduct the heat through the bridge to the Chassis.

In other embodiments, the metal bridge can be just a metal block without recess region. It can be tight to either side of the transistor with resistor mounted on the top surface or side surface.

In other embodiments, the transistor can have a package base with the same size as ceramic portion. The metal bridge can then be mounted directly to the chassis over the top of the transistor.

In one embodiment, the transistor, 100, is a Gallium Nitride (GaN) transistor. Broadband performance from 20 MHz to 2500 MHz has been achieved. The output power is 20 Watt across the entire frequency band. In other embodiments, performance beyond this data can be also achieved.

Since the feedback phase length is minimized, it is able to operate stably; making this amplifier to be the first broadband stable high power GaN feedback amplifier.

The transistor is not limited to a GaN transistor. The disclosed feedback structure can also used with high power Silicon, Silicon Carbide or GaAs transistors (such as LDMOS, SiC or GaAs MESFET, pHEMT) or integrated circuits to achieve high output power over extraordinary bandwidth.

Although various exemplary embodiments of the invention have been disclosed, it should be apparent to those skilled in the art that various changes and modifications can be made which will achieve some of the advantages of the invention without departing from the true scope of the invention. These and other obvious modifications are intended to be covered by the appended claims.

We claim:

1. A broadband feedback power amplifier comprising:
an active device;
a feedback structure comprising a bridge and a resistor with the resistor mounted on the bridge which is then mounted over the active device.

2. The amplifier of claim 1 wherein the said active device is a GaN (Gallium Nitride) device.

3. The amplifier of claim 1 wherein the said active device is a Silicon device.

4. The amplifier of claim 1 wherein the said active device is a transistor.

5. The amplifier of claim 1 wherein the said active device is an integrated circuit.

6. The amplifier of claim 1 wherein the said active device is in a flange package.

7. The amplifier of claim 1 wherein the said bridge is made out of metal.

8. The amplifier of claim 1 wherein the said bridge is made out of non-metal material with high thermal conductivity.

9. The amplifier of claim 1 wherein the said bridge is comprised of at least one recess region.

10. The amplifier of claim 1 wherein the said wherein the said bridge is a block without recess region.

11. The amplifier of claim 1 wherein the said wherein the said resistor is surface mount.

12. The amplifier of claim 1 wherein the said resistor is mounted on the top surface of the bridge.

13. The amplifier of claim 1 wherein the said resistor is mounted on the back side of the bridge.

14. The amplifier of claim 1 wherein the said resistor is mounted on the side of the bridge.

15. A feedback structure for power amplifier comprising:
a bridge;
a resistor. The resistor is mounted on the bridge.

16. The feedback structure of claim 15 wherein the bridge is mounted over an active device.

17. The feedback structure of claim 16 wherein the active device is a GaN (Gallium Nitride) device.

18. The feedback structure of claim 16 wherein the active device is a Silicon device.

19. The feedback structure of claim 15 wherein the said bridge is made out of metal.

20. The feedback structure of claim 15 wherein the said bridge is made out of non-metal material with high thermal conductivity.

21. The feedback structure of claim 15 wherein the said bridge is comprised of at least one recess region.

22. The feedback structure of claim 15 wherein the said wherein the said bridge is a block without recess region.

23. The feedback structure of claim 15 wherein the said wherein the said resistor is surface mount.

24. The feedback structure of claim 15 wherein the said resistor is mounted on the top of the bridge.

25. The feedback structure of claim 15 wherein the said resistor is mounted on the back of the bridge.

26. The feedback structure of claim 15 wherein the said resistor is mounted on the side of the bridge.
